(19) United States
(12) Patent Application Publication
(10) Pub. No.: US 2013/0104957 A1
(43) Pub. Date: May 2, 2013

(54) METHOD FOR PRODUCING A PHOTOVOLTAIC MODULE HAVING BACKSIDE-CONTACTED SEMICONDUCTOR CELLS, AND PHOTOVOLTAIC MODULE

(71) Applicants: Metin Koyuncu, Kernen (DE); Ulrich Schaaf, Kaisersbach (DE); Andreas Kugler, Alfdorf (DE); Patrick Zerrer, Weinstadt (DE); Martin Zippel, Berlin (DE); Patrick Stihler, Wolfschlugen (DE)

(72) Inventors: Metin Koyuncu, Kernen (DE); Ulrich Schaaf, Kaisersbach (DE); Andreas Kugler, Alfdorf (DE); Patrick Zerrer, Weinstadt (DE); Martin Zippel, Berlin (DE); Patrick Stihler, Wolfschlugen (DE)

(21) Appl. No.: 13/640,878

(22) PCT Filed: Oct. 26, 2010
(86) PCT No.: PCT/EP2010/066122

§ 371 Date: Jan. 16, 2013

(30) Foreign Application Priority Data
Apr. 14, 2010 (DE) 102010027747.9

(51) Int. Cl. H01L 31/05

(52) U.S. Cl. CPC H01L 31/05
USPC 136/244; 438/73; 438/16

(57) ABSTRACT

A method for producing a photovoltaic module having backside-contacted semiconductor cells which have contact regions provided on a contact side includes: providing a foil-type, non-conducting substrate having an at least one-sided and at least sectionally electrically conductive substrate coating on a first substrate side; placing the contact sides of the semiconductor cells on a second substrate side; implementing a local perforation which penetrates the substrate and the substrate coating, to generate openings at the contact regions of the semiconductor cells; applying a contact element to fill the openings and to form a contact point between the substrate coating on the first substrate side and the semiconductor cells on the second substrate side.

### BACKGROUND OF THE INVENTION

1. Field of the Invention

The present invention relates to a method for producing a photovoltaic module having backside-contacted semiconductor cells, and to a photovoltaic module.

2. Description of the Related Art

Photovoltaic modules based on semiconductors known from the related art are made up of a totality of semiconductor cells. Under the influence of external incident light an electrical voltage is produced inside these cells. The semiconductor cells are expediently interconnected so that the highest possible current intensity can be picked off at the photovoltaic module. This requires contacting of the semiconductor cells and expedient line wiring within the photovoltaic module.

The known photovoltaic modules use what is known as ribbons for the wiring and cabling. Usually, these are conductor segments made of metal, especially copper, which are developed in the form of strips. The contacting between a ribbon and the semiconductor cells to which it is wired usually is implemented as a soft solder connection. The contacts are routed from an upper, light-active side of a semiconductor cell to a rear side, facing away from the light, of an adjacent semiconductor cell. Situated at the contact points between the ribbon and the semiconductor cell are metallized contact regions in which the soldered connection is implemented.

To increase the light yield of such photovoltaic modules, tests have been carried out to place the described contacting points entirely on the rear side of the semiconductor cells, which faces away from the light. In such a case the side facing away from the light forms a contact side of the individual semiconductor cell. The contact regions situated on the common contact side must then be contacted using a different potential. Given a multitude of semiconductor cells in an interconnection to be realized, and a given geometric arrangement, this requirement places considerable demands on the precision of the contactings if faulty wiring and short-circuit connections are to be avoided in reliable manner. The difficulties this entails with regard to the precise positioning of the semiconductor cells in a given cell arrangement have the result that the backside contacting, which is advantageous with regard to the energy yield of the photovoltaic module, requires a complicated manufacturing process, which, above all, hampers an efficient large-scale production of such modules.

### BRIEF SUMMARY OF THE INVENTION

The method for producing a photovoltaic module having backside-contacted semiconductor cells which have contact regions provided on a contact side includes the following method steps:

A foil-type, non-conducting substrate is provided, which has an at least one-sided and at least sectionally electrically conductive substrate coating on a first substrate side. The contact sides of the semiconductor cells are then placed onto a second substrate side. Then, a local perforation which punctures the substrate and the conductive substrate coating is carried out in order to produce openings in the contact regions of the semiconductor cells. As next step, a contacting means is applied in order to fill the openings and to form contacting points between the substrate coating on the first substrate side and the semiconductor cells on the second substrate side.

Thus, a substrate foil which is provided with a conductive coating on at least one side forms the basis. The semiconductor cells are placed on the other side of the substrate. As a result, their contact sides are resting directly on the substrate. Then, precisely the particular contact regions of the semiconductor cells that are to be electrically contacted are exposed by a perforation process. The openings produced in the substrate in the process are filled so as to be conductive and thus form a contacting point between the contact regions and the substrate coating.

The semiconductor cells may be fixed in place by plastic strips, e.g., by EVA tape, during the perforation. For practical purposes, a plastic material is used which is also utilized for laminating the photovoltaic module or its component, if appropriate.

One great advantage of the method is that positional inaccuracies in the placement of the semiconductor cells, which sometimes occur in large-scale manufacturing processes, do not cause any problem. The actual locations of the contacting areas between the semiconductor cells and the conductive substrate coating are specified only when the contacting is imminent. This makes it possible to allow the placement process of the semiconductor cells to take place at relatively generous manufacturing tolerances.

In one specific embodiment, a lamination step for laminating the semiconductor cells is expediently implemented after the semiconductor cells have been placed on the substrate. This permanently joins the semiconductor cells to the substrate, thereby preventing them from changing their positions during subsequent method steps. In addition, the entity made up of the substrate and the laminated semiconductor cells forms a composite, which is able to be stored and held in readiness for the subsequent method steps without any problems.

As an alternative, it is also possible to laminate a substrate glass of the photovoltaic module during the same lamination step.

It is easily possible to produce additional contacting layers. For practical purposes, at least one additional contacting layer is produced after the contacting means has been applied, and the following method steps are executed in so doing:

The contacted substrate coating is at least sectionally covered by an insulating cover layer. Next, a local perforation which punctures the cover layer, the substrate and/or the substrate coating is carried out in order to produce openings in the contact regions of the semiconductor cells. In the next step, a contacting means is applied on the cover layer to fill the openings and to form the contacting layer extending on the cover layer.

Various methods may be used to apply the contacting means in the individual contacting layer. Printing, spraying or soldering are among the options. When the soldering is performed, a solder dispenser carries a solder material to the opening to be filled, where the solder material is deposited after melting. In one expedient specific embodiment, the selective soldering is implemented as laser soldering. In this case the melting is accomplished by an application of laser light.

For practical purposes, image recognition of the semiconductor cells situated on the substrate is performed during the local perforation process, and direct referencing of a perforation device on each individual semiconductor cell is implemented via image processing and/or reference-point setting.

This detects the actual location of each individual semiconductor cell in situ, which means that the sections provided for the contacting also are exposed precisely at the locations that were detected in the image. This is the reason why the high positional tolerance in the placement of the semiconductor cells has no disadvantageous effect on the actual contacting process.

In one practical specific embodiment, an x-ray device performs the image recognition. It generates an x-ray image. In so doing, a contour is detected for each x-ray image during the image processing, and the result of the contour detection is used to automatically move the perforation device to a position determined in the contour detection process in order to produce the individual opening.

In one practical embodiment, the local perforation is performed in the form of laser drilling using a laser drill device. This allows the perforation to be carried out in very precise and contactless manner.

Provided on the side of the device is a photovoltaic module, which includes a totality of semiconductor cells having backside contacting and a substrate; in the present invention the photovoltaic module is characterized by the fact that the substrate is implemented as a foil or a laminate, and the substrate has openings in the region of the semiconductor cells filled with a conductive material so as to form a contact point between the semiconductor cells situated on one side of the substrate, and circuit tracks of conductive material which extend on another side of the substrate.

For practical purposes, the conductive material is developed as conductive laminate, ink, paste or solder.

### BRIEF DESCRIPTION OF THE DRAWINGS

FIG. 1 shows an illustration of the placement step of the semiconductor cells on the substrate.

FIG. 2 shows a lamination step of the semiconductor cells placed on the substrate.

FIG. 3 shows an illustration of the local perforation of the substrate.

FIG. 4 shows an illustration of a contacting process by the introduction of solder.

FIG. 5 shows an illustration of a further layer configuration with the local perforation as an additional step.

FIG. 6 shows an illustration of a further contacting step.

FIG. 7 shows an illustration of an x-ray process for determining the position of the contact regions.

### DETAILED DESCRIPTION OF THE INVENTION

FIG. 1 shows a placement step for semiconductor cells on a substrate. Semiconductor cells 1 shown here are developed as crystalline photovoltaic cells, for instance. They are made of silicon or a comparable semiconductor material and include the doped regions (not shown here in detail) for the energy conversion of solar energy into electrical voltage. Each semiconductor cell has a contact side 2 which features contact regions 3 disposed thereon. The contact regions usually are galvanically metallized. A placement device, which is not shown here, is normally used for the placement.

A substrate 4 is provided for the backside contacting of the semiconductor cells and, in particular, their contact sides 2. This substrate is made of a foil-type, electrically insulating material or a laminate of electrically non-conductive foils. The fixation of the semiconductor cells on the substrate is accomplished by means of a plastic foil 4a. This foil is made of, for example, ethylene vinyl acetate (EVA) in the form of a tape applied as strips.

As an alternative, the semiconductor cells may also be bonded to the substrate in non-conductive manner. In such a case the substrate has an adhesive surface, which is not denoted here specifically. Pertinent specific embodiments are illustrated in the following, in FIGS. 5 through 7.

Substrate 4 has been provided with an electrically conductive substrate coating 5, which has been applied on one side in this instance. It may be developed as vapor-deposited metal layer or as a metal foil which is joined to the substrate in the form of a laminate. The substrate coating may be developed across the entire surface or applied only in sections. In the example shown, the coating is provided in the form of large-scale areas, which are subdivided by a series of trenches 6. The coating is made of copper, for example, or another material having the same excellent electrical conductivity, by which a series resistance of the semiconductor cells to be contacted is able to be reduced. In the present example, the semiconductor cells are situated on the electrically insulating side of the substrate.

Instead of depositing the semiconductor cells, printing, vapor-depositing or laminating (not shown here) a suitable material so as to realize organic cells are also options. In such a production process, a polymer acting as organic semiconductor, especially a conjugated polymer having a corresponding electron structure, or a specially synthesized hybrid material is applied on the foil-type substrate. The composite formed thereby is highly flexible, sufficiently thin and very easy to process, and the method steps described in the following text are likewise able to be executed without any problems.

Other conductive materials, especially conductive polymers or conductive oxides such as indium tin oxide (ITO), for example, also may be used for the electrically conductive substrate coating. However, their electrical conductivity is sometimes lower than that of metallic coatings.

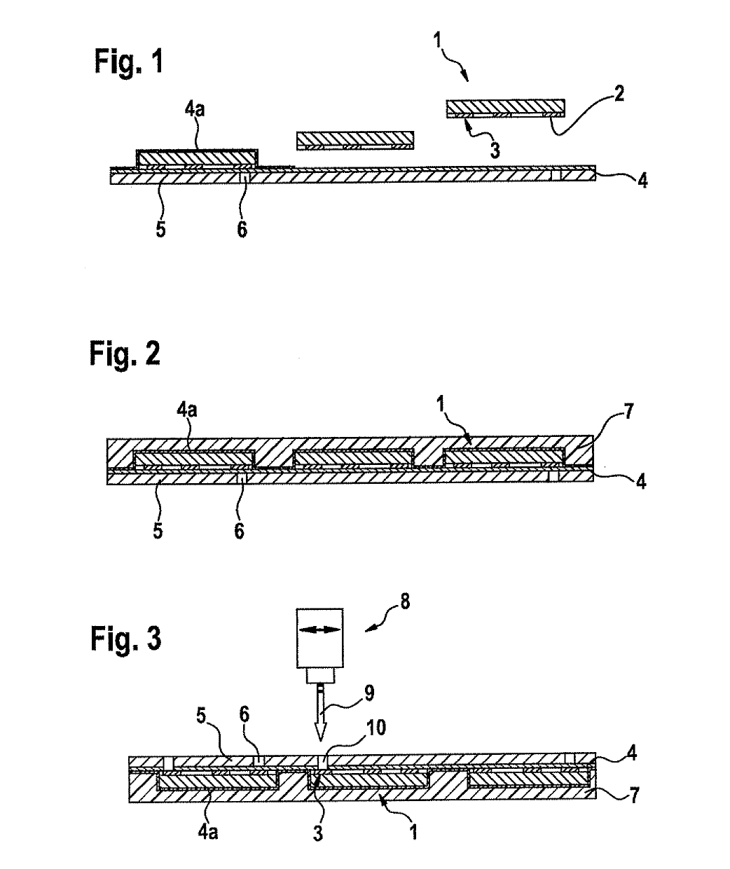

In the example at hand, the placement process illustrated in FIG. 1 is followed by an encapsulation step shown in FIG. 2. In the process, the semiconductor cells located on the substrate are covered by a laminate 7. A plastic foil, for example, may be used for the lamination, which is then applied in the course of a vacuum lamination process. Especially ethylene vinyl acetate (EVA) is suitable for the lamination. Both materials are able to be used to thermoplastically form a cover over the totality of the semiconductor cells. It is useful if the laminate is made of the same material as the plastic foil or tape 4a used for the fixation of the semiconductor cells.

As an alternative to the thermoplastic lamination, the use of reactive lamination materials, known as “dam and fill”, among others, is also an option. These are in particular substances or mixtures of substances that are castable or spreadable, cure in transparent fashion under the action of electromagnetic radiation and/or heat, and in so doing, transparently encapsulate the totality of the semiconductor cells on the substrate. The use of a plastic material on the basis of organosilicon compounds (silicon) is an option in this case.

Depending on the requirements, the lamination and encapsulation process illustrated in FIG. 2 is combinable with a lamination on a glass substrate (not shown here) of the later photovoltaic module. The glass substrate is placed directly on the laminate, and the laminate simultaneously brings about the connection of the composite of semiconductor cells and foil on the glass substrate. In such a case the following method steps are implemented on a practically finished photovoltaic module, on which only the backside contacting still needs to be produced.

As illustrated in FIG. 3, the composite shown in FIG. 2 is expediently rotated for the further method steps. Substrate 4, especially its conductive substrate coating 5, now forms its top surface.

The composite is now locally perforated at predefined locations. The local perforation in the example shown is carried out by a laser drill device 8. This device moves toward contact regions 3 situated on the semiconductor cells and covered by the substrate, and emits a laser beam 9 in the direction of the composite at the required locations. A separate opening 10 at which a contact region 3 is exposed is produced at the points that were impinged upon. An opening may have a point shape or also the shape of a line or an area. Both are able to be achieved in a very simple manner by the laser drilling device.

The locations on the composite of semiconductor cells and substrate provided for the local perforation are determined in advance with the aid of an x-ray process, which will be discussed in greater detail below, within the framework of image detection. The laser drill device utilizes the positional information determined in the process and in this way approaches each individual position. Possible positional differences of the semiconductor cells due to the manufacturing process therefore do not affect the outcome and are completely compensated for.

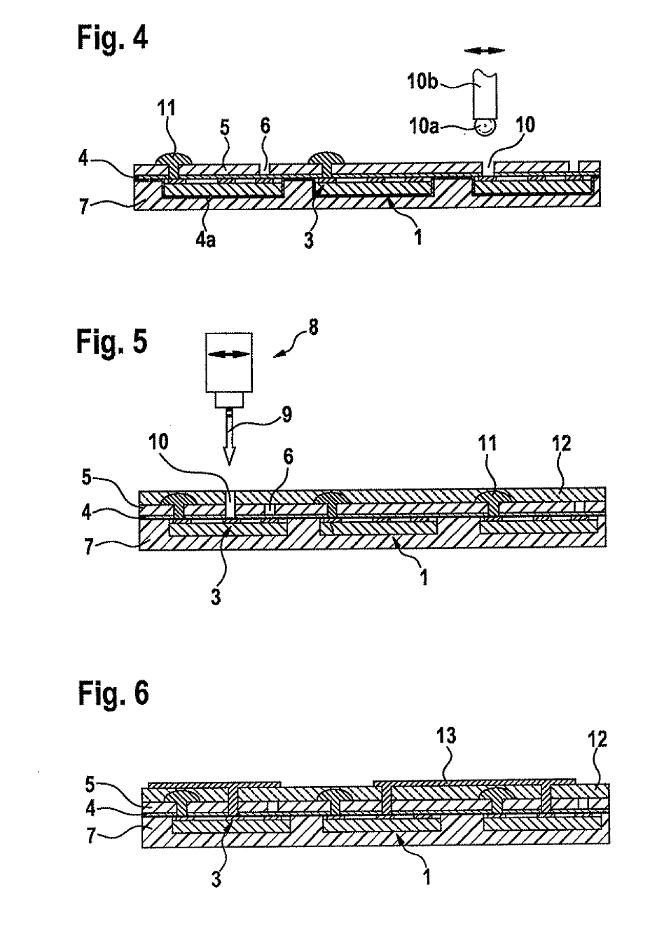

FIG. 4 illustrates the subsequent backside contacting of the semiconductor cells. In this method step previously created openings 10 are filled with a conductive material. The contacting of the contact regions is produced at the semiconductor cells having conductive substrate coating 5.

In the example shown in the figure, a solder dispenser 10b moves the conductive material in the form of a solder drop 10a of a solder paste or a solder ball toward opening 10 provided for this purpose, and deposits it there. This is followed by selective melting of the contact region and the solder paste or the solder ball, and a contacting 11 is formed between contact region 3 and conductive substrate coating 5. A laser soldering method may be utilized for this purpose. It has shown to be useful to subject the openings in the substrate produced in the perforation process to a separate metallization in order to ensure proper wetting by the solder. The metallization is implementable by vapor deposition, printing or spraying.

Instead of a soldering process, point-by-point or line-type printing or deposition of paste or conductive ink is able to take place as well. Each contacting process may be carried out in image-controlled manner, it being possible to use for this purpose the image recognition unit already utilized for the local perforation, and/or the positional data obtained in that process.

In such a case, for example, the laser drill device may introduce the opening at a particular location intended for this purpose; subsequently the position to which the move was made may be transmitted to an adjustment device of the solder dispenser, whereupon a move to a next position takes place, while the contacting is produced at the opening just created. In such a method sequence, the perforation and the contacting thus occur basically within a single working process.

It is pointed out here that, basically, any method for filling openings 10 with conductive material that ensures a reliable electrical contacting 11 of contact regions 3 at semiconductor cells 1 having conductive substrate coating 5 may be used in this context. An alternative to the previously already mentioned procedures, for example, additional suitable methods, especially spray methods, may be used for the contacting.

Among the suitable spray methods are, for instance, cold gas spraying, plasma spraying using a plasma jet, flame spraying using a wire or rod, flame spraying using powder, plastic flame spraying, high-velocity flame spraying (HVOF), detonation spraying, laser spraying, arc spraying, or also PTA (plasma transferred arc), a few of these methods being discussed in greater detail in the following paragraphs.

During cold gas spraying, a heated process gas is accelerated to supersonic speed by expansion in a Laval nozzle of a spray head and formed into a gas jet in the process, into which the conductive material as spray material is injected in the form of cold particles. The particles themselves are thereby accelerated and strike the locations to be contacted with high kinetic energy. During the impingement, they then form the desired contacting in the form of dense, firmly adhering layers. In contrast to other thermal spray techniques, this method has the advantage that no prior initial fusing or hotmelting is required. In addition, the temperature of the process gas lies under the melting point of the spray material, so that the structure of the spray material, i.e., the conductive material, advantageously does not change. Furthermore, the thermal loading of the substrate is low. In addition, a clearly controllable spray jet geometry in most cases ensures the application of conductive material without a masking need. Finally, this also keeps the spray losses to a negligible level.

On the other hand, if the contacting is realized by plasma spraying, a plasma stream, a so-called plasma jet, emerges from a plasma head having a plasma source, into which the conductive material as spray material has been injected in the form of powder particles. The plasma jet pulls the powder particles along and hurls them onto the spots to be contacted. In an advantageous manner, the plasma spraying is optionally possible in a normal atmosphere, an inert atmosphere, in a vacuum or, if necessary, also under water.

The two alternative methods of “cold gas spraying” or “plasma spraying” share the following advantages: Both methods may be carried out at moderate temperatures. In addition, it is also possible to use such conductive materials as aluminum or iron, for example, which are barely able to be processed in the soldering method. Also, especially aluminum is considerably more cost-effective than copper and thus offers a savings potential for the contacting. Apart from that, there is no need to provide solderable locations at the spots to be contacted. For example, it is possible to dispense with a silver paste for providing solderable areas. This, too, makes it possible to provide a larger area for the so-called back surface field (BSF).

The positioning of the spray head in the cold gas spray method or the positioning of the plasma head for a plasma spraying is similar to the positioning of solder dispenser 10b in FIG. 4, which means that solder dispenser 10b with solder drop 10a in FIG. 4 is to be replaced by the spray head or the plasma head. The spray head or the plasma head is also able to be moved from a current position to a next position using the same procedure as described earlier already for solder dispenser 10b.

It is basically possible to apply at least one additional contacting track or plane. One pertinent example is shown in FIGS. 5 and 6. To deposit the next contacting plane, the previously produced contacting points 11 are covered by an electrically insulating cover layer 12. For example, the cover layer may be deposited by a lamination process, for which the conventional materials, especially an EVA foil, are able to be utilized. In the composite produced in this manner, in a repeat application of the previously described perforation method step shown in FIG. 3, in particular the laser drilling, additional openings 10 are produced at additional contact regions 3 of the semiconductor cells. They are then filled with another conductive material 13 and connected to each other, so that a second layer of circuit tracks forms in the process.

Different methods may be used to deposit and apply conductive material 13. In addition to the mentioned laser soldering method, it is possible to use a printing method in which an ink or paste having high conductivity, especially a nano-Ag ink or paste, is usable as conductive material.

Furthermore, the various spray methods described earlier may be used to deposit and apply conductive material 13. This creates filled openings 10 and a second circuit track layer.

Vapor deposition or plotting of the conductive material is possible as well. In so doing, it is useful to first fill the created openings by depositing conductive drops. The positional data required for this purpose may be called up, as described, from a position memory or a control unit of the laser drill device. Then the required circuit tracks between the individual contacting points are calculated. The calculated paths are translated into control pulses, which in turn are transmitted to a drive mechanism for a plotter pen or a vapor deposition nozzle. The drive mechanism thereupon moves the plotter pen or the vapor deposition nozzle across cover layer 12. The plotter pen or the vapor deposition nozzle deposits conductive material 13 along the provided paths. In so doing, they produce the second contacting plane for the placement of the semiconductor cells.

It is clear that the method steps elucidated with reference to FIGS. 5 and 6 may basically be run through multiple times. In principle, any number of contact planes may be deposited in addition, in order to thereby obtain more complex connections of the semiconductor cells. It is possible to insert additional electronic components, especially diodes, for instance in order to produce bypass diode circuits between the semiconductor cells.

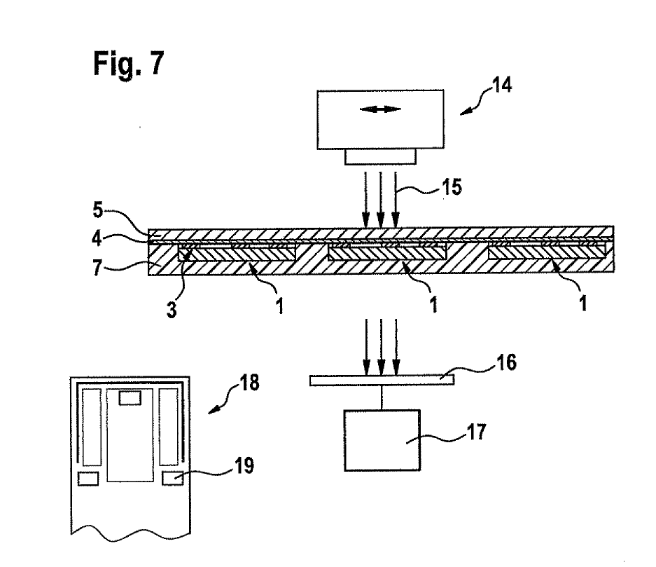

FIG. 7 shows an illustration of the scanning process mentioned earlier already. The x-ray device provided for this purpose consists of a movable radiation source 14 to generate radiation 15 that penetrates the composite. An x-ray source may be used as radiation source.

The radiation is detected using an array 16, the array recording an x-ray image of a semiconductor cell 1 situated in the beam path. The raw data determined in this manner are transmitted to an image processing unit 17, especially a computer on which an image processing program has been installed.

The image processing device performs a structure detection on the x-ray image, during which the positions of the forms contained in the image are determined, stored and forwarded to a control unit of the laser drill device and/or the solder dispenser, and to a corresponding other device for applying the contacting planes.

Additionally, a schematic x-ray image 18 of a segment of a semiconductor cell is illustrated. Due to the increased absorption capacity of the metallized contact regions, they show up in the form of clearly recordable contours 19, whose position is able to be determined unambiguously.

The image recognition of the contact regions may also be replaced or supplemented by detecting a fiducial. In this case, semiconductor cells containing definite reference structures that are clearly visible in the x-ray image are set down on the substrate, the position of each contact region to be exposed in relation to the reference structures being known in advance, which thus allows them to be calculated from the position of the fiducial. In particular cross structures that define a local coordinate system for each individual semiconductor cell may be used as fiducial. This coordinate system is recorded by the image-generating method. The position of each individual contact region within the coordinate system is known in advance for each semiconductor cell. This makes it possible to determine the contact regions from the position of the fiducial, even in those cases where these regions do not show any contour in the x-ray image.

The method according to the present invention and the structure of the photovoltaic module produced in the process were discussed on the basis of exemplary embodiments. Additional developments and modifications are possible within the scope of the actions of an expert. Such developments and modifications result from the dependent claims, in particular.

1-12. (canceled)

13. A method for producing a photovoltaic module having backside-contacted semiconductor cells which each include contact regions provided on a contact side, comprising:
providing a foil-type, non-conducting substrate having an at least one-sided and at least sectionally electrically conductive substrate coating on a first substrate side;
placing the contact sides of the semiconductor cells on a second substrate side;
performing a local perforation which penetrates the substrate and the substrate coating to produce openings in the substrate at the contact regions of the semiconductor cells; and
depositing a first contacting element in order to fill the openings and to form contacting points between the substrate coating on the first substrate side and the semiconductor cells on the second substrate side.

14. The method as recited in claim 13, wherein the semiconductor cells are covered in a lamination process after the contact sides have been placed on the substrate.

15. The method as recited in claim 13, further comprising:
providing at least one further contacting layer after the first contacting element has been deposited, wherein the providing of the at least one further contacting layer includes:
at least sectionally covering the contacted substrate coating by an insulating cover layer;
performing a local perforation which punctures at least one of the insulating cover layer, the substrate and the conductive substrate coating, in order to produce openings in the contact regions of the semiconductor cells; and
depositing a second contacting element on the insulating cover layer to fill the openings and to form the further contacting layer extending on the cover layer.

16. The method as recited in claim 15, wherein the depositing of the first and second contacting elements is implemented by one of printing, spraying or soldering.

17. The method as recited in claim 16, wherein:
the depositing of the first and second contacting elements is implemented by soldering;
during the soldering, a solder dispenser carries a solder material to the openings to be filled; and
the solder material is melted and subsequently deposited into the openings.

18. The method as recited in claim 17, wherein:
the soldering is implemented as laser soldering, and the melting of the solder material is accomplished by an application of laser light.

19. The method as recited in claim 15, wherein the depositing of the first and second contacting elements is implemented by a spray method.

20. The method as recited in claim 19, wherein the spray method includes one of: cold gas spraying; plasma spraying using a plasma jet; flame spraying using one of a wire or rod; flame spraying using powder; plastic flame spraying; high velocity oxygen spraying; detonation spraying; laser spraying; light arc spraying; or plasma transferred arc.

21. The method as recited in claim 13, wherein an image recognition of the semiconductor cells situated on the substrate is performed when the local perforation is carried out, and direct referencing of a perforation device on each individual semiconductor cell is implemented via at least one of image processing and reference-point setting.

22. The method as recited in claim 21, wherein:
an x-ray image is produced by an x-ray radiography device for the image recognition, a contour detection being implemented for the x-ray image during the image recognition; and
based on the result of the contour detection, the perforation device is automatically moved to a specified position in order to produce the individual opening.

23. The method as recited in claim 22, wherein the local perforation is implemented as laser drilling using a laser drill device.

24. A photovoltaic module, comprising:
a substrate; and
multiple semiconductor cells each having backside contacting;
wherein the substrate is one of a foil or a laminate, and wherein the substrate has openings in the region of the semiconductor cells, the openings being filled to be electrically conductive and to form a contact point between the semiconductor cells on a first substrate side and circuit tracks extending on a second substrate side.
